(19) United States
(12) Patent Application Publication
(10) Pub. No.: US 2008/0112037 A1
(43) Pub. Date: May 15, 2008

(54) HERMETIC SEALING OF MICRO DEVICES

(75) Inventors: Shaoher X. Pan, San Jose, CA (US); Vlad Novotny, Los Gatos, CA (US)

Correspondence Address: FISH & RICHARDSON P.C., PO BOX 1022, MINNEAPOLIS, MN, 55440-1022, US

(73) Assignee: SPATIAL PHOTONICS, INC., Sunnyvale, CA (US)

(21) Appl. No.: 11/558,888

(22) Filed: Nov. 10, 2006

(51) Int. Cl. G02B 26/00; H01L 21/52

(52) U.S. Cl. 359/291; 438/114; 257/E21.5

(57) ABSTRACT

A method for packaging a micro device includes encapsulating a micro device in a chamber on a substrate, wherein the chamber is defined by spacer walls and an encapsulation cover, removing a portion of the encapsulation cover and portions of the spacer walls to expose a surfaces of the spacer walls, and forming a layer of a sealing material on the exposed surfaces of the spacer walls to hermetically seal the micro device in the chamber.

### BACKGROUND

The present disclosure relates to the packaging of micro devices.

In manufacturing micro devices, multiple micro devices are commonly fabricated on a semiconductor wafer. The micro devices are subsequently packaged and separated into individual dies. Many types of micro devices must be in a hermetically sealed environment to prevent damage to the micro devices and ensure a long useful life of the device. It is therefore desirable to have an efficient process for providing hermetic sealing of the multiple micro devices on the semiconductor wafer.

### SUMMARY

In one general aspect, the present invention relates to a method for packaging a micro device, the method including encapsulating a micro device in a chamber on a substrate, wherein the chamber is defined by spacer walls and an encapsulation cover; removing a portion of the encapsulation cover and portions of the spacer walls to expose one or more surfaces of the spacer walls; and forming a layer of a sealing material on the exposed surfaces of the spacer walls to hermetically seal the micro device in the chamber.

In another general aspect, the present invention relates to a method for packaging micro devices, the method including encapsulating a plurality of micro devices on a substrate in chambers that are defined by spacer walls and an encapsulation cover; removing portions of the encapsulation cover and portions of the spacer walls to expose surfaces of the spacer walls; and forming a layer of a sealing material on the exposed surfaces of the spacer walls to hermetically seal the micro devices in the chambers.

In another general aspect, the present invention relates to an encapsulated micro device on a substrate. A micro device is on a substrate within a chamber, an encapsulation cover in part defining the chamber. One or more spacer walls are between the substrate and the encapsulation cover, wherein at least one of the spacer walls has an inner surface adjacent to the micro device and an outer surface opposite to the inner surface, and the outer surface is sloped relative to the substrate. A sealing material is on the outer surface of the spacer walls, hermetically sealing the chamber.

Implementations of the system and methods described herein may include one or more of the following features. The one or more exposed surfaces of the spacer walls can include a surface that is sloped relative to the substrate. The step of forming the encapsulated device can include anisotropically depositing the sealing material on a surface that is sloped relative to the substrate. The step of removing portions of the cover or walls can include cutting the encapsulation cover and the portions of the spacer walls. The spacer walls can include a low out-gassing material, epoxy or spacer particles. At least a portion of the encapsulation cover can be transparent to visible, UV, or IR light. The encapsulation cover can include an opaque aperture layer having an opening over the micro device. The method of forming the device can include forming a layer of sacrificial material on the encapsulation cover before the step of removing and removing the layer of sacrificial material and the sealing material on the sacrificial material. Forming the layer of the sealing material may include forming the layer of sealing material on the sacrificial material and the exposed surfaces of the spacer walls to hermetically seal the micro device in the chamber. The method can include cutting a portion of the substrate and separating the chamber encapsulating the micro device from an adjacent chamber encapsulating an adjacent micro device on the substrate. The method can include removing a portion of the spacer wall and a portion of the encapsulation cover to expose electric contacts on the substrate, where the electric contacts are configured to send electric signals to or receive electric signals from the micro device. The step of removing can comprise dissolving a portion of the spacer wall or an adhesive bonding the spacer wall and the substrate.

Various implementations of the methods and devices described herein may include one or more of the following advantages. The disclosed system and methods may provide an effective approach for hermetically sealing a micro device on a substrate. The sealing material can be anisotropically deposited on sloped surfaces on a chamber that encapsulates the micro device, and may hermetically seal the device within the chamber. Another potential advantage of the disclosed system and methods is that a plurality of micro devices can be simultaneously hermetically sealed in one or more chambers at high throughput.

Although the invention has been particularly shown and described with reference to multiple embodiments, it will be understood by persons skilled in the relevant art that various changes in form and details can be made therein without departing from the spirit and scope of the invention.

### BRIEF DESCRIPTION OF THE DRAWINGS

The following drawings, which are incorporated in and form a part of the specification, illustrate embodiments of the present invention and, together with the description, serve to explain the principles, devices and methods described herein.

FIGS. 1A-1I illustrate steps for encapsulating a micro device on a substrate using an encapsulation cover having inorganic spacer walls.

FIG. 2 is a flowchart showing the steps in FIGS. 1A-1I.

FIGS. 3A-3I illustrate steps for encapsulating a micro device on a substrate using an encapsulation cover having spacer walls made of an organic material.

FIG. 4 is a flowchart showing the steps in FIGS. 3A-3I.

FIGS. 5A-5E illustrate steps for encapsulating a micro device on a substrate.

FIG. 6 is a flowchart showing the steps in FIGS. 5A-5E.

### DETAILED DESCRIPTION

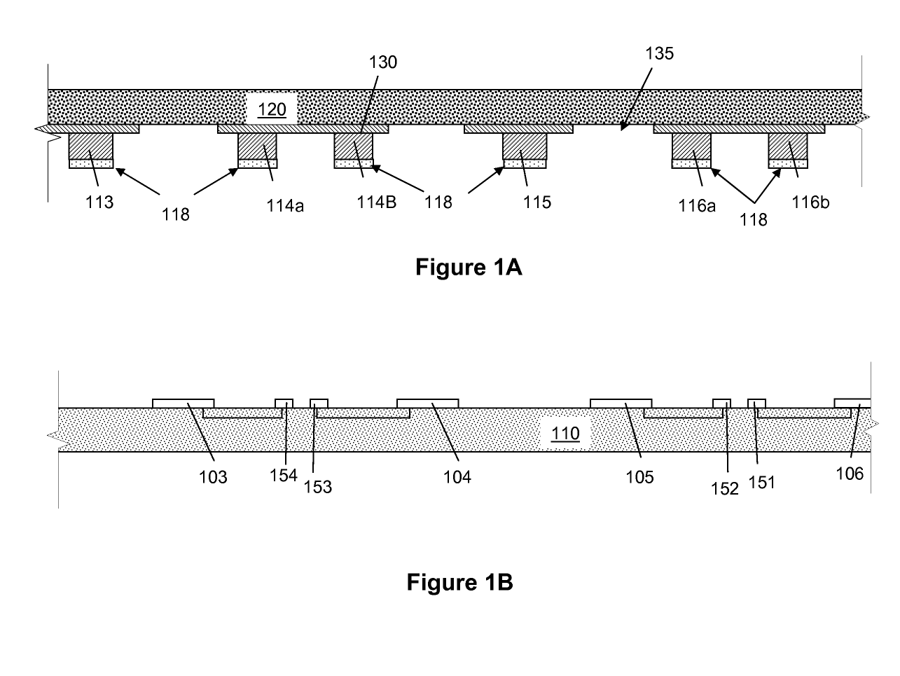

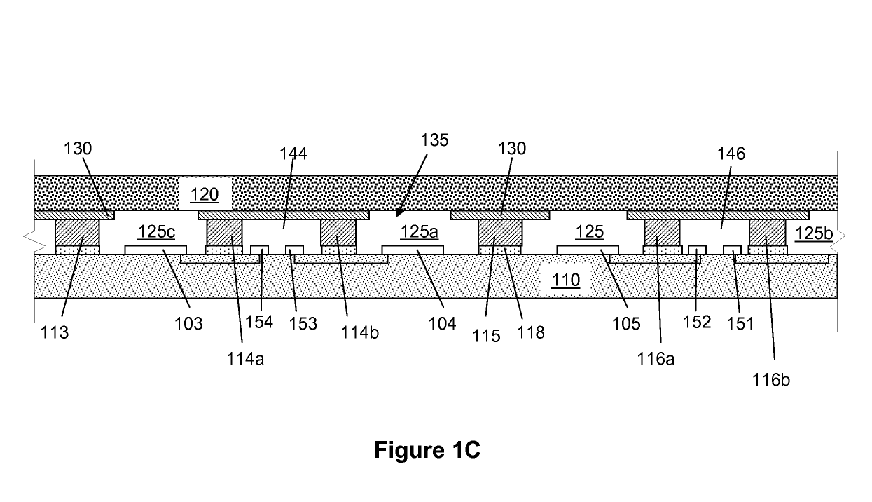

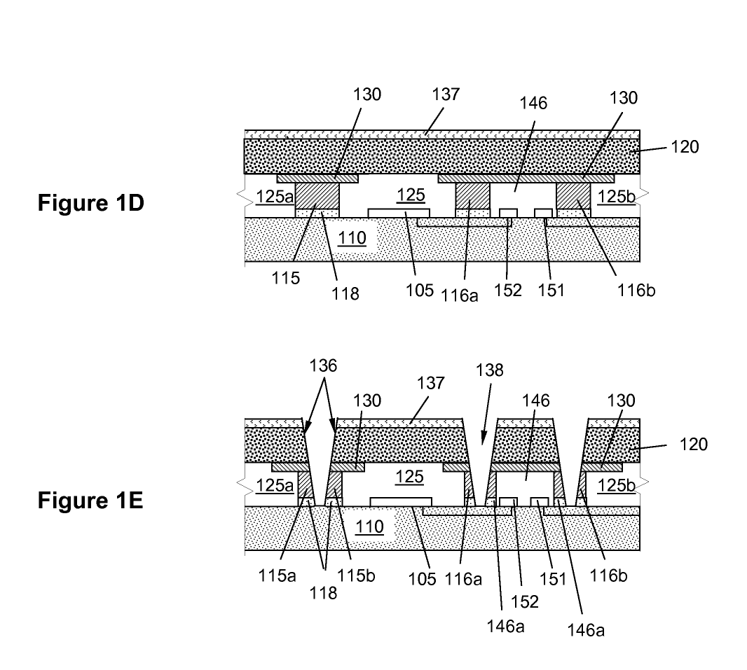

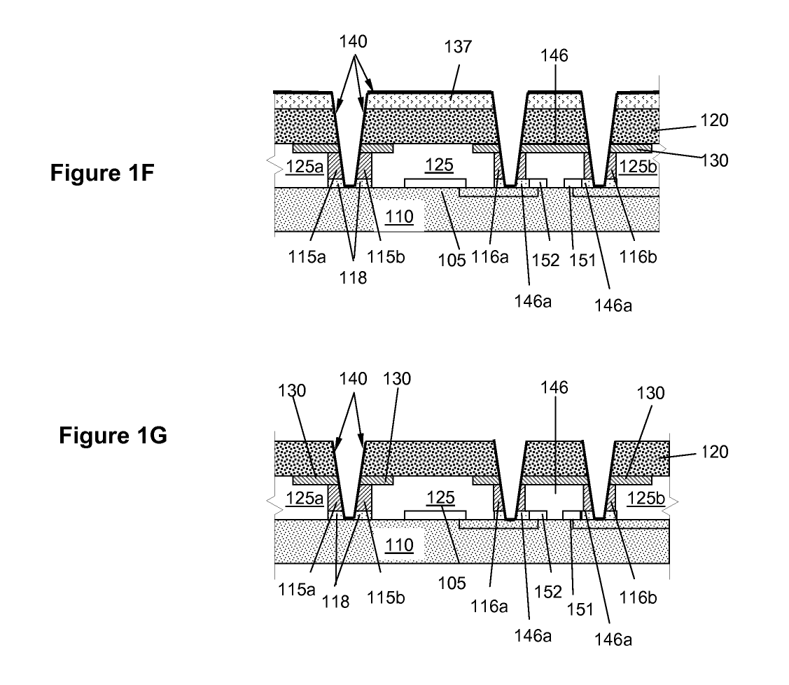

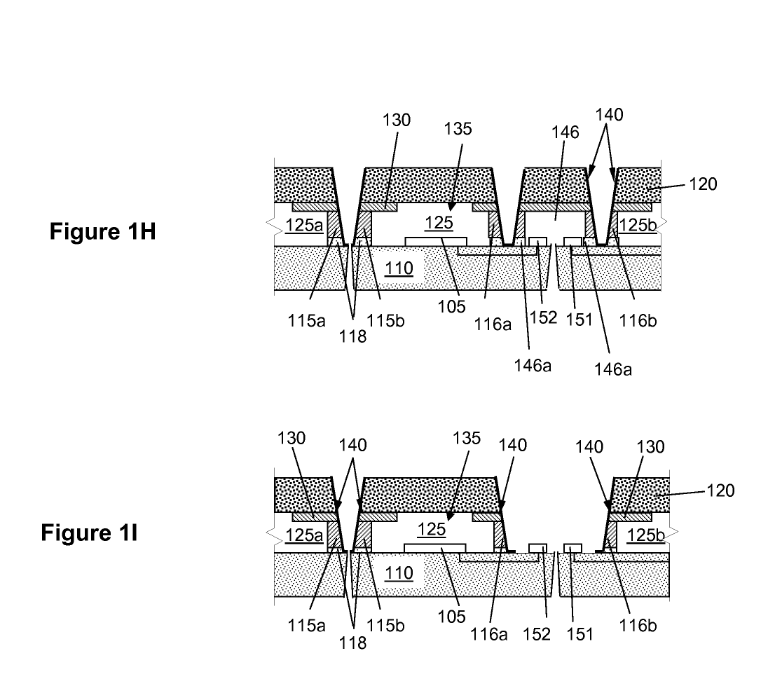

Referring to FIGS. 1A and 1B, micro devices 103-106 are formed or mounted onto a substrate 110. For example, the micro devices 103-106 can be mounted on the substrate by wire bonding or flip-chip bonding. The micro devices 103-106 are respectively electrically connected to electric contacts 151-154 on the substrate 110. The electric contacts 151-154 allow the micro devices 103-106 to receive external electric signals or to output electric signals. The electric contacts 151-154 can be distributed in a fan-out pattern to allow easy access. The micro device is a microstructure that can produce a mechanical movement, electromagnetic signals, acoustic signals, or optical signals in response to an input signal. The micro device can include Micro-Electro Mechanical Systems (MEMS) such as an array of tiltable micro mirrors, integrated circuits, micro-sensors, micro-actuators, light emitting elements and other such devices.

An opaque aperture layer 130 can be formed on the lower surface of an encapsulation cover 120. The encapsulation cover 120 can be made of a material that is transparent to visible, UV, or IR light. The encapsulation cover 120 can thus allow optical communications with the micro devices 103-106 after they are encapsulated. Furthermore, the encapsulation cover 120 is impermeable to fluid and gas. The aperture layer 130 can be made of a material capable of blocking light, such as a metallic material, e.g., chromium or light absorbing material, such as chromium oxide.

The aperture layer 130 can include openings 135 to define transparent windows formed over the micro devices 103-106. Spacer walls 113, 114a, 114b, 115, 116a, and 116b are formed on the aperture layer 130. The spacer walls can be made of an inorganic material, such as glass, metal, silicon, ceramic or other suitable material. In some embodiments, an opaque aperture layer 130 can be formed on the upper surface of the encapsulation cover 120 such that the aperture layer 130 will be positioned at the exterior of the encapsulation chambers that encapsulate the micro devices 103-106.

Referring to FIGS. 1A-1C, a polymer adhesive 118 such as an epoxy is applied to the lower surfaces of the spacer walls 113-116b. Alternately, the polymer adhesive 118 can also be disposed on the upper surface of the substrate 110. The encapsulation cover 120 is pressed against the substrate 110. The polymer adhesive 118 seals the lower surfaces of the spacer walls 113-116b and the upper surface of the substrate 110 (step 210). The micro devices 103-106 are respectively encapsulated in separate encapsulation chambers 125, 125a, 125b, and 125c. The electric contacts 151-154 are positioned in separate chambers 144 and 146. In some embodiments, each encapsulation chamber 125, 125a, 125b, or 125c holds more than one micro device. In some embodiments, the polymer adhesive 118 is permeable to air and moisture. The polymer adhesive 118 needs to be properly sealed in order to hermetically encapsulate a micro device in a chamber, as discussed below.

A layer of sacrificial material 137, such as a photo resist, is next formed on the encapsulation cover 120 (FIG. 1D, step 220). The sacrificial material 137 is selected so that it can be removed and lift off a layer of material (i.e., sealing material 140) deposited on the sacrificial material 137. Because sealing material 140 is often opaque, removing the sealing material 140 can maintain window clarity in the encapsulation cover 120 over the micro device 125, which is required for optical communications and inspection.

Portions of the encapsulation cover 120 and portions of the spacer walls 115a, 1115b, 116a and 116b are removed to produce encapsulation chambers 125, 125a, and 125b separated by spaces 138 (FIG. 1E, step 230). The spaces 138 can be in the shape of a reverse trapezoid that includes a portion of the upper surface of the substrate 110 below the spaces 138. The surfaces 136 facing the spaces 138 are sloped, that is, formed at a non-perpendicular angle relative to the substrate 110. The sloped surfaces 136 form portions of the outer surfaces of the encapsulation chambers 125, 125a, and 125b. The encapsulation cover 120 and the spacer walls 115 can be cut at an oblique angle to the substrate 110 to produce the sloped surfaces 136. The cutting can be performed with a mechanical cutter, such as a diamond blade that can be shaped to define the spaces 138 between the encapsulation chambers 125, 125a, and 125b. The sloped surfaces 136 can also be cut by a narrow mechanical cutter along an oblique direction relative to the substrate 110. A laser can also be used to cut the spacer walls 115, 116. The laser beam can be profiled to produce the desired V-shape of the spaces 138. The cutting separates spacer walls 115, 116 into spacer walls 115a, 115b, 116a and 116b that define different encapsulation chambers 125, 125a, and 125b, each of which can contain one or more micro devices 105. The cutting is controlled to proceed entirely through the encapsulation cover 120, the aperture layer 130 and the spacer walls 115, 116, but stops at or just before the surface of the substrate 110 to avoid cutting into the substrate or an electric circuit in the substrate. In practice, some residual polymer adhesive 118 may remain after the cutting operation. The surfaces of the spacer walls 115a, 115b, 116a and 116, the polymer adhesive 118 and the substrate 110 are optionally cleaned by reactive ion etching to remove the residual polymer adhesive and debris of the spacer walls 115a-116b from the cutting step (step 240).

A layer of a sealing material 140 on the sloped surfaces 136 is next formed on the spacer walls 115a, 115b, 116a and 116b and the sacrificial material 137 that is on the encapsulation cover 120 (FIG. 1F, step 250). The sealing material 140 also seals the outer surface of the polymer adhesive 118 to prevent gas leakage into the chamber 125 through the polymer adhesive 118. The cleaned surface on the substrate 110 below the spaces 138 is free of polymer adhesive materials, which ensures depositing of the sealing material 140 on the substrate 110 and proper sealing of the encapsulation chamber 125. The sealing material 140 is a material that is impermeable to fluid and gas or has very low permeability to fluid and gas, such as a metallic material, silicon oxide, or silicon nitride. The sealing material 140 can have a thickness between about 2 and 100 microns on the sloped surfaces 136. The layer of the sealing material 140 forms a barrier to prevent air or moisture from entering the encapsulation chamber 125 in which the micro device 105 is encapsulated. In other words, the layers of the sealing material 140 can hermetically seal the micro device 105 in the encapsulation chamber 125.

One advantageous feature of the sloped surfaces 136 is that they can receive anisotropic material depositions from a material source positioned above the substrate 110. The sealing material 140 can be anisotropically deposited by physical vapor deposition (PVD) using a material target source located above the substrate 110. The lateral extensions of the sloped surfaces 136 allow the sloped surfaces 136 to receive the sealing material 140. The rate of deposition on the sloped surface 136 is reduced by a factor of cosine of the angle between a sloped surface 136 and the upper surface of the substrate 110 in comparison with a non-sloped surface on the substrate 110 and the non-sloped upper surfaces of the sacrificial material 137 on the encapsulation cover 120. Thus, the layer of the sealing material 140 is thicker on the non-sloped surfaces than on the sloped surfaces 136. The duration of deposition can be controlled to ensure a continuous layer of sealing material 140 with a desired thickness is formed on all the sloped surfaces 136.

The sacrificial material 137 and the sealing material 140 on the sacrificial material 137 is removed from the non-sloped top surface of the encapsulation cover 120 (FIG. 1G, step 260). The sacrificial material 137 can be removed by wet etching, a dry plasma etching or if the sacrificial material is a resist, by developing the resist. The sealing material 140 on the sacrificial material 137 is lifted off in the removal process. The sealing material 140 remains on the sloped surfaces 136 to hermetically seal the spacer walls 115a, 115b, 116a and 1116b. The sacrificial material 137 provides a simple means for removing the sealing material 140 from areas of the device where it is not desired, such as in regions where the sealing material would interfere with the device functioning properly. Removal of the sacrificial material 137 can be selective so that the encapsulation cover 120 is not damaged or modified during the removal process.

The substrate 110 is next cut through from the lower surface in the spaces 138 between adjacent encapsulation chambers, e.g., chambers 125 and 125a, that contain micro devices. The substrate 110 is also cut through from the lower surface in areas below the chambers in which the electrical contacts are located, e.g., chamber 146. For example, the cut can be in a spot between electric contacts 151 and 152 and away from the electric circuits in the substrate 110 (FIG. 1H, step 270). The substrate 110 is then soaked in a solvent, such as acetone, to allow the solvent to enter the chamber 146. The solvent is selected such that it can dissolve the polymer adhesive 146a and 146b but does not attack the sealing material 140. The solvent comes to contact with the inside surfaces of the polymer adhesive 146a and 146b under the spacer walls. The solvent etches the polymer adhesive 146a and 146b until the polymer adhesive 146a and 146b are removed (step 280). The outside surfaces of the polymer adhesives in the chamber 146 are protected by the sealing material 140. The sealing material 140 on the polymer adhesive 146a and 146b is lifted off and removed. The encapsulation cover 120 over the electric contacts 151 and 152 separates from the substrate 110 to expose the electric contacts 151 and 152. The micro device 105 is enclosed on a separate die as shown in FIG. 1I. The exposed electric contacts 151 and 152 can be conveniently accessed to apply electric signals to or receive electric signals from the micro device 105.

Because the encapsulation cover 120 is impermeable to fluid and gas, one or more hermetically sealed encapsulation chambers 125, 125a, and 125b are formed on the substrate 110 using the steps described herein. Each hermetically sealed encapsulation chamber 125 encapsulates one or more micro devices 105. In some embodiments, the encapsulation chambers 125, 125a, and 125b are evacuated prior to the encapsulation of the micro devices 105. The hermetic sealing of the encapsulation chambers 125, 125a, and 125b maintains a stable environment in the encapsulation chambers 125, 125a, and 125b, which can help keep the micro device 105 operating properly. In devices where the encapsulation chamber is under vacuum, the hermetic sealing of the encapsulation chamber maintains the vacuum state. In some embodiments, the environment is not a vacuum environment, but is a gas that has been selected for the device to operate in.

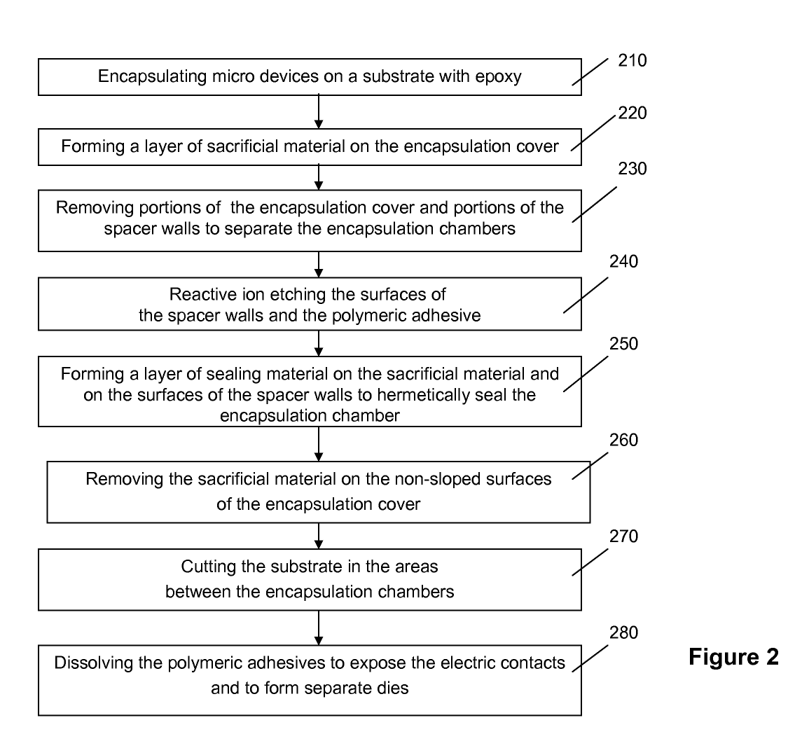

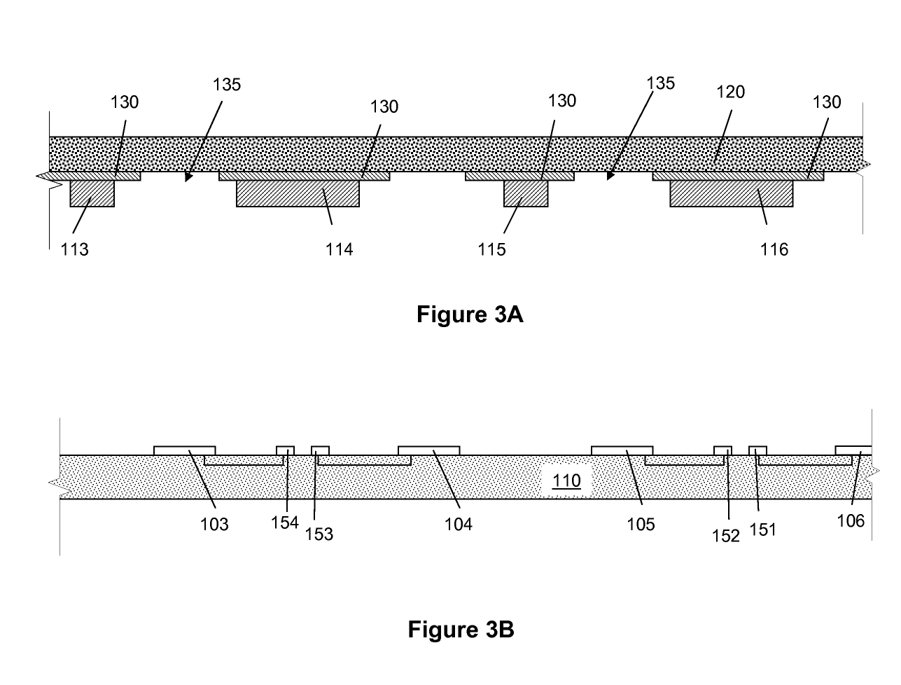

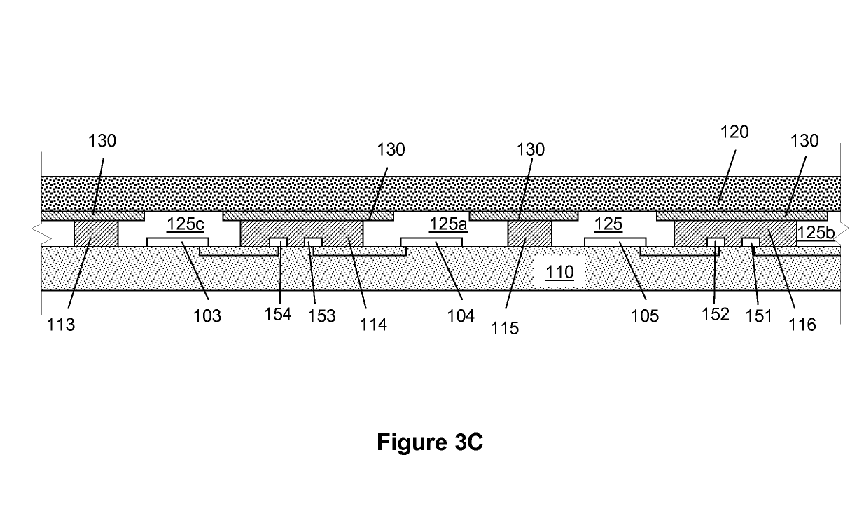

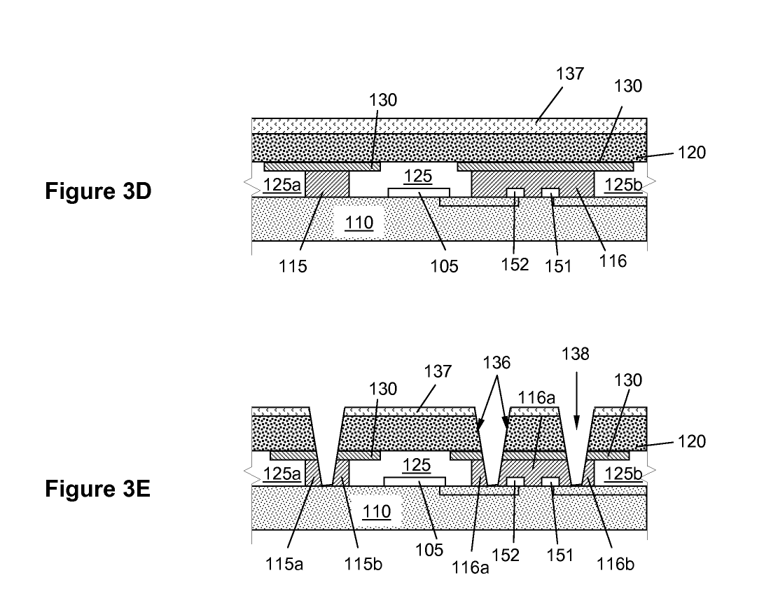

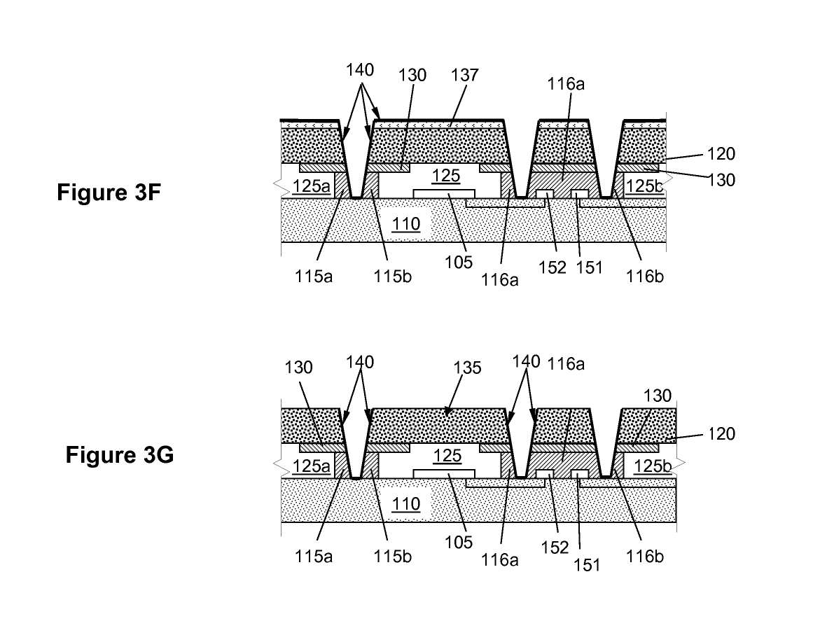

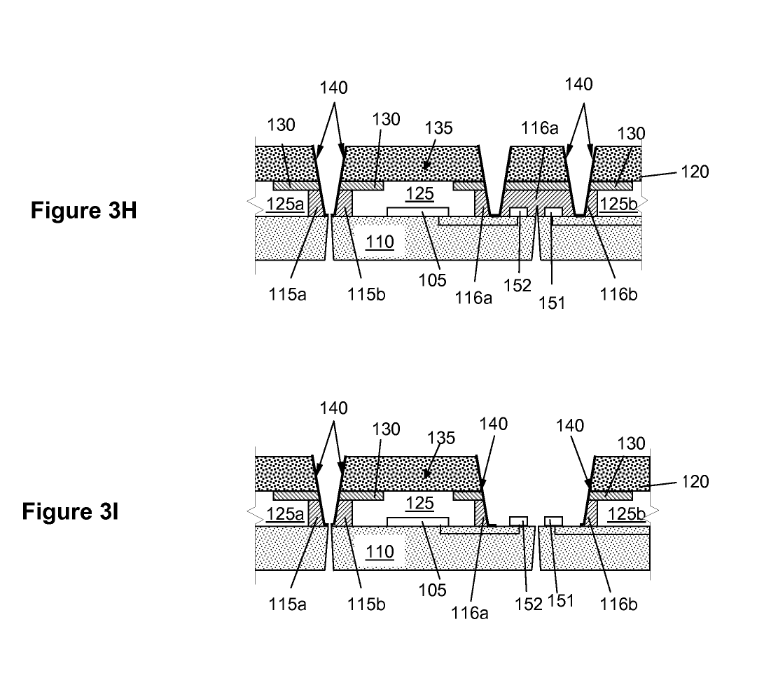

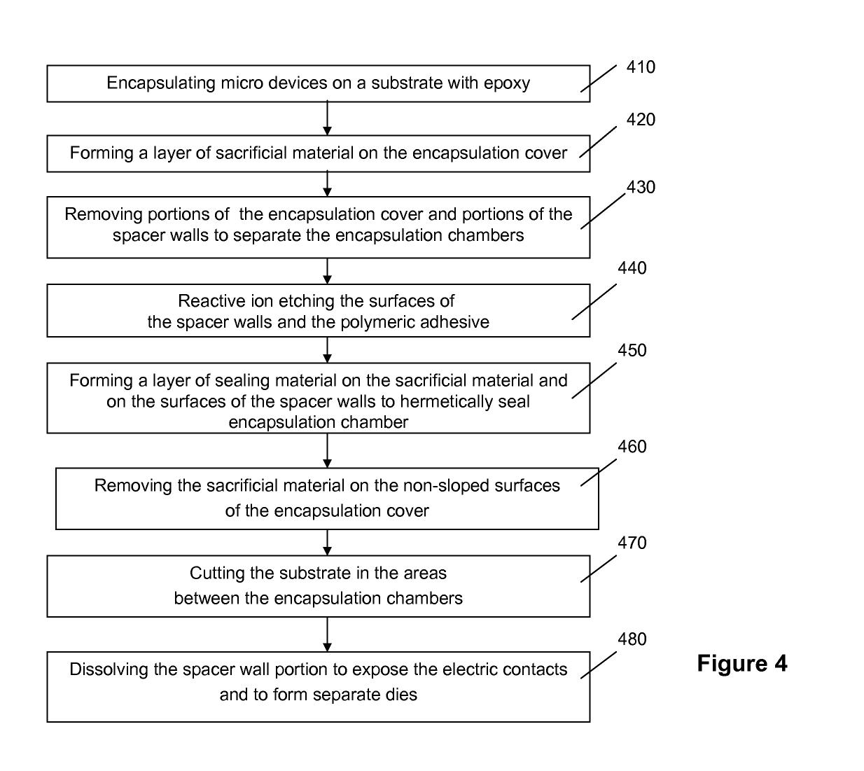

Other embodiments are illustrated in FIGS. 3A-3I, and in the flow chart in FIG. 4. The processes disclosed in FIGS. 3A-3I and FIG. 4 are similar to that disclosed above in conjunction with FIGS. 1A-1I and FIG. 2, with one difference being that the spacer walls 113-116 are made of organic materials, such as a solidified epoxy. The spacer walls 113-116 are permeable to gas and can be dissolved by a solvent such as acetone. The polymer adhesive that seals the spacer walls 113-116 with the substrate 110 can form as part of the spacer wall 113-116 (FIG. 3C, step 410). When the lower surface of the substrate 110 is cut, the cuts extend through the substrate and expose the spacer wall 116a (FIG. 3H, step 470). The solvent dissolves the spacer wall 116a made of the organic material to expose the electric contacts 151 and 152 and separate the micro device 125 on separate dies (FIG. 3I, step 480).

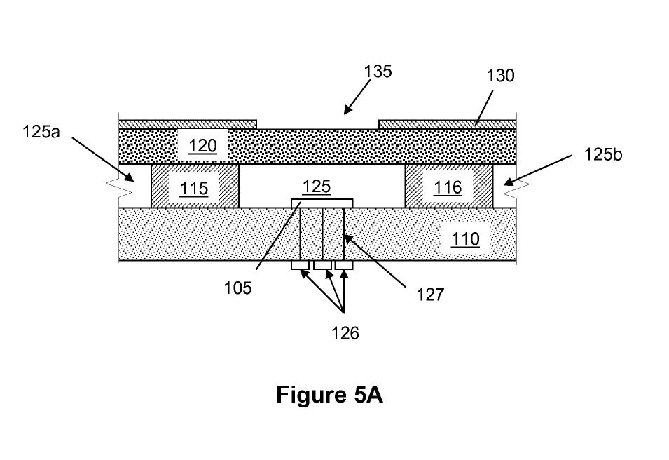

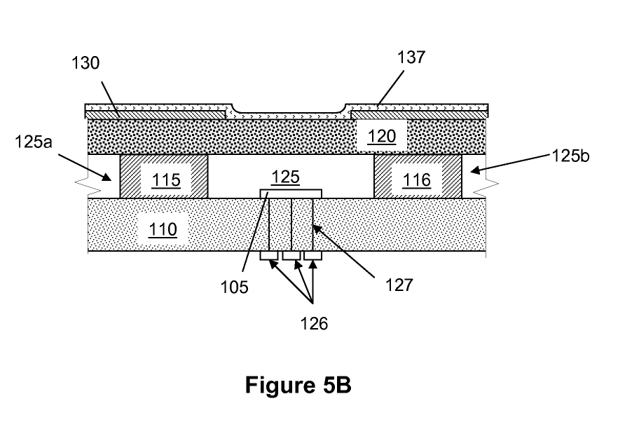

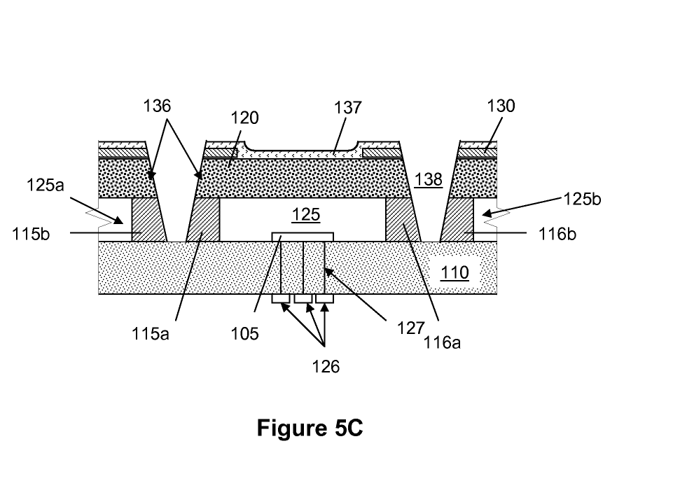

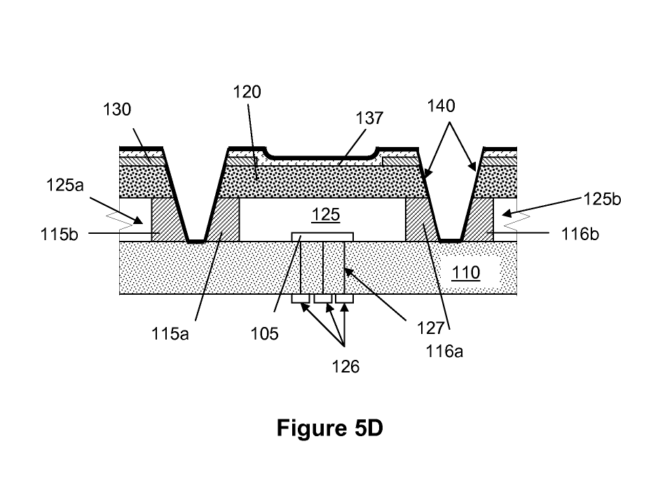

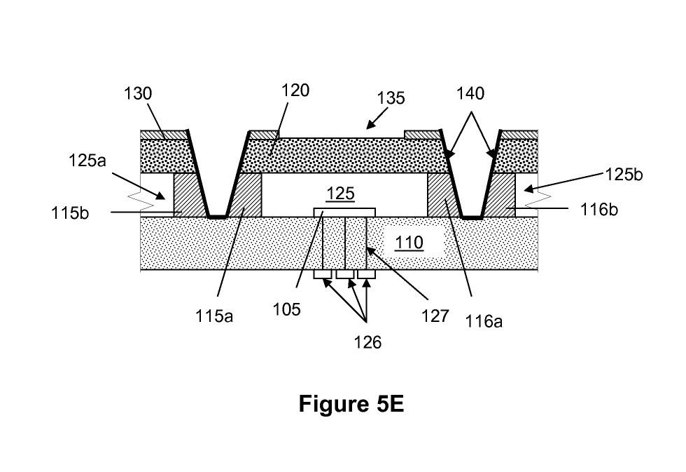

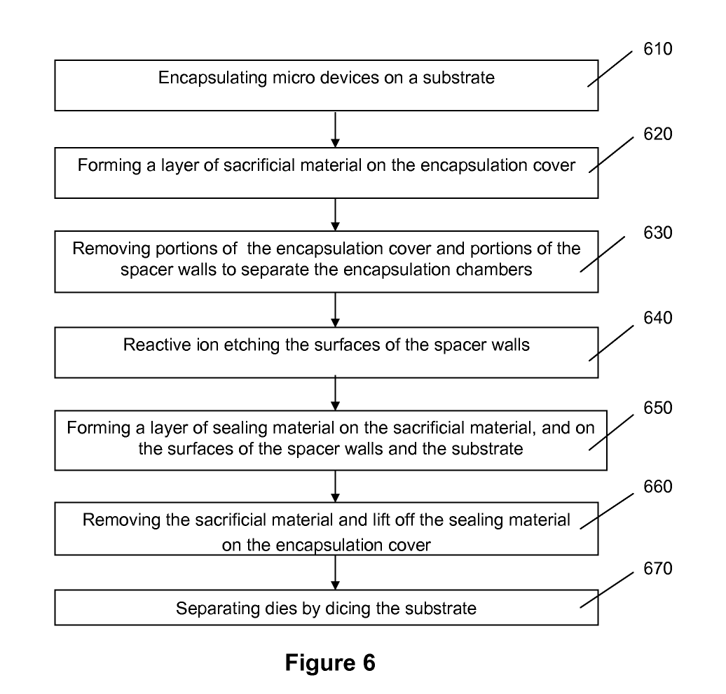

In some embodiments, referring to FIGS. 5A to 5E, a micro device 105 formed or mounted onto a substrate 110 is encapsulated within an encapsulation chamber 125 defined by spacer walls 115, 116 and an encapsulation cover 120 (step 610). The micro device 105 is electrically connected with electric contacts 126 on the lower surface of the substrate 110 by electric circuit 127 in the substrate 110. The electric contacts 126 allow the micro device 125 to be externally controlled by electric signals or to output electric signals.

The encapsulation cover 120 is unitarily connected to or sealed to the upper surfaces of the spacer walls 115, 116. The spacer walls 115, 116 can be made of a polymer material, such as epoxy, that is permeable to air and moisture. In some embodiments, the spacer walls 115, 116 include a low out-gassing material that does not release a significant amount of gas. Examples of the low out-gassing material include glass, metallic and ceramic materials. The low out-gassing material in the spacer walls 115, 116 prevents gases from escaping the walls 115, 116 and entering the encapsulation chamber 125. Such gases can interfere with the functioning of the device 105, such as by forming a coating on surfaces of the device or attacking the device 105. The spacer walls 115, 116 can also optionally include spacer particles 117 which can reduce the volume of low out-gassing material needed in the spacer walls 115, 116, and define the distance between the encapsulation cover 120 and the substrate 110.

The encapsulation cover 120 can be made of a material, such as glass, that is transparent to visible, UV, or IR light. Furthermore, the encapsulation cover 120 is impermeable to fluid. In some embodiments, an opaque aperture layer 130 is formed on the encapsulation cover 120. The aperture layer 130 can be formed on either the exterior of the encapsulation cover 120 or on a side of the encapsulation cover 120 adjacent to the device 105. The opaque aperture layer 130 includes an opening 135 over the micro device 105 to allow for optical communications with the micro device 105. That is, the micro device 105 can receive, transmit or both receive and transmit light through the opening 135. The opaque aperture layer 130 can be made of a material capable of blocking light, such as a metallic material, e.g., chromium.

A plurality of micro devices 105 can be formed on the substrate 110. The micro devices 105 can be encapsulated in encapsulation chambers 125, 125a, and 125b, and are separated by the spacer walls 115, 116. In some embodiments, each encapsulation chamber 125, 125a, or 125b holds more than one micro device 105. The aperture layer 130 on the encapsulation cover 120 includes openings over each of the micro devices 105.

A layer of sacrificial material 137 is formed on the encapsulation cover 120 (FIG. 5B, step 620). The sacrificial material can be material that can be selectively removed without damaging layers below the material, such as a photo resist. Photo resist can be spin-coated on the encapsulation cover 120. When an aperture layer 130 covers part of the encapsulation cover 120, the sacrificial material 137 can cover both the aperture layer 130 and any openings 135 therein.

Portions of the encapsulation cover 120 and portions of the spacer walls 115, 116 are subsequently removed to produce encapsulation chambers separated by spaces 138 (FIG. 5C, step 630). The surfaces 136 facing the spaces 138 are sloped, e.g., formed at a non-perpendicular angle, relative to the substrate 110. The sloped surfaces 136 form portions of the outer surfaces of the encapsulation chambers 125, 125a, and 125b. The encapsulation cover 120 and the spacer walls 115 can be cut along directions oblique relative to the substrate 110 to produce the sloped surfaces 136. The cutting can be conducted by a mechanical cutter, such as a diamond blade that is shaped to define the spaces 138 between the encapsulation chambers 125, 125a, and 125b. A laser can also be used to cut the spacer walls 115, 116. The laser beam can be profiled to produce the desired v-shape of the spaces 138. The cuts extend at least as far as the top surface of substrate 110 and can cut part way into the substrate 110. The cutting separates spacer walls 115, 116 into spacer walls 115a, 115b, 116a and 116b that define different encapsulation chambers 125, 125a, and 125b, each of which can contain one or more micro devices 105. The surfaces of the spacer walls 115a, 115b, 116a and 116b are next subjected to reactive ion etching to clean off residual polymer adhesive 118 on the substrate 110 from the cutting process (step 640). The cleaning of the surface of the substrate 110 ensures the sealing material to be deposited on the substrate 110 and also covers the end of the bonding interface between the spacer walls 115a, 115b, 116a and 116b and the substrate 110.

A sealing material 140 is next applied to the sloped surfaces 136 on the spacer walls 115a, 115b, 116a and 116b and the sacrificial material 137 on the encapsulation cover 120 (FIG. 5D, step 650). The cleaned surface on the substrate 110 below the spaces 138 allows the sealing material 140 to be deposited on the substrate 110 to ensure the proper sealing of the encapsulation chamber 125. The sealing material 140 is a material that is impermeable to fluid or has very low permeability to fluid, such as a metallic material, a silicon oxide, or silicon nitride. The sealing material 140 can have a thickness between about 2 and 100 microns on the sloped surfaces 136. The layer of the sealing material 140 forms a barrier to prevent air or moisture from entering the encapsulation chamber 125 in which the micro device 105 is encapsulated. In other words, the layers of the sealing material 140 can hermetically seal the micro device 105 in the encapsulation chamber 125.

One advantageous feature of the sloped surfaces 136 is that they can receive anisotropic material depositions from a material source above the substrate 110. The sealing material 140 can be anisotropically deposited by physical vapor deposition (PVD) using a material target source located above the substrate 110. The lateral extensions of the sloped surfaces 136 allow the sealing material 140 to be received by the sloped surfaces 136. The rate of deposition for the sloped surface 136 is reduced by a factor of cosine function of the angle between a sloped surface 136 and the upper surface of the substrate 110 in comparison with a non-sloped surface on the substrate 110 and the non-sloped upper surfaces of the sacrificial material 137 on the encapsulation cover 120. Thus, the layer of the sealing material 140 is thicker on the non-sloped surfaces than on the sloped surfaces 136. The duration of the deposition can be controlled to ensure a continuous layer of sealing material 140 is formed on all the sloped surfaces 136.

FIG. 5E shows the device after some of the sacrificial material 137 and the sealing material 140 on the sacrificial material 137 has been removed from a region around the opening 135, e.g., from the non-sloped top surface of the encapsulation cover 120 and aperture layer 130 (FIG. 5E, step 660). The sacrificial material can be removed by wet etching, a dry plasma etching or if the sacrificial material is a resist, by developing the resist. The sealing material 140 remains on the sloped surfaces to hermetically seal the spacer walls 115a, 115b, 116a and 116b. The sacrificial material 137 provides a simple means for removing the sealing material 140 from areas of the device where it is not desired, such as in regions where the sealing material would interfere with the device functioning properly. Removal of the sacrificial material 137 can be selective so that the encapsulation cover 120 is not damaged or modified during the removal process.

Because the encapsulation cover 120 is impermeable to fluid, one or more hermetically sealed encapsulation chambers 125, 125a, and 125b are formed on the substrate 110 using the steps described herein. Each hermetically sealed encapsulation chamber 125 encapsulates one or more micro devices 105. In some embodiments, the encapsulation chambers 125, 125a, and 125b are evacuated prior to the encapsulation of the micro devices 105. The hermetic sealing of the encapsulation chambers 125, 125a, and 125b maintains a stable environment in the encapsulation chambers 125, 125a, and 125b, which can help keep the micro device 105 operating properly. In situations where the encapsulation chamber is under vacuum, the hermetic sealing of the encapsulation chamber maintains the vacuum environment for the micro device. In some embodiments, the environment is not a vacuum environment, but is a gas that has been selected for the device to operate in.

Once the individual encapsulation chambers are formed, optionally, the lower surface of the substrate 110 in the areas of the substrate 110 between the encapsulation chambers 125, 125a, and 125 can be cut to separate the encapsulation chambers into individual dies (step 670). The cutting location can be selected between the electric contacts 126 on the lower surface of the substrate 110 and away from the electric circuit 127 in the substrate 110. The substrate 110 can be scored and manually broken, diced, sawed or otherwise cut to separate the dies from one another. In some embodiment, the cuts that form sloped surface 136 and spaces 138 also score the substrate 110 for separation.

It is understood that the disclosed systems and methods are compatible with techniques for the application of a sealing material to spacer walls having a sloped side. The sealing material and the materials for the spacer walls can be selected from a wide range of low permeability materials. The disclosed system and methods are also compatible with different configurations and material selections of the encapsulation cover and the spacer walls without deviating from the spirit of the present specification. An anti-reflective coating may be formed on both surfaces of the encapsulation cover. The micro devices compatible with the disclosed system and methods can include MEMS, integrated circuits, spatial light modulators such as an array of tiltable micro mirrors, micro sensors, micro actuators, and light emitting elements. Furthermore, the substrate can include electric circuits necessary for providing the electrical signals to control the micro devices. In particular, the substrate can include a complimentary-metal-oxide semiconductor (CMOS) devices. Although encapsulation at the die level has been described, the encapsulation process described herein can also be applied at the wafer level for sealing or packaging.

What is claimed is:

1. A method for packaging a micro device, comprising:
encapsulating a micro device in a chamber on a substrate, wherein the chamber is defined by spacer walls and an encapsulation cover;
removing a portion of the encapsulation cover and portions of the spacer walls to expose a surface of the spacer walls; and
forming a layer of a sealing material on the exposed surface of the spacer walls to hermetically seal the micro device in the chamber.

2. The method of claim 1, wherein the exposed surface of the spacer walls comprises a surface that is sloped relative to the substrate.

3. The method of claim 2, wherein the step of forming comprises depositing the sealing material on the surface that is sloped relative to the substrate.

4. The method of claim 1, wherein the step of removing comprises cutting the encapsulation cover and the portions of the spacers.

5. The method of claim 1, wherein the spacer walls comprise a low out-gassing material.

6. The method of claim 5, wherein the spacer walls comprise epoxy, glass, metal or silicon.

7. The method of claim 1, wherein at least a portion of the encapsulation cover is transparent to visible, UV, or IR light.

8. The method of claim 1, wherein the encapsulation cover comprises an opaque aperture layer having an opening over the micro device.

9. The method of claim 1, further comprising:
forming a layer of sacrificial material on the encapsulation cover before the step of removing; and
removing the layer of sacrificial material and the sealing material on the sacrificial material, wherein forming the layer of the sealing material includes forming the layer of sealing material on the sacrificial material and the exposed surface of the spacer walls to hermetically seal the micro device in the chamber.

10. The method of claim 1, further comprising:
cutting a portion of the substrate; and
separating the chamber encapsulating the micro device from an adjacent chamber encapsulating an adjacent micro device on the substrate.

11. The method of claim 10, further comprising removing a portion of the spacer wall and a portion of the encapsulation cover to expose an electric contact on the substrate, where the electric contact is configured to send an electric signal to or receive an electric signal from the micro device.

12. The method of claim 11, wherein the step of removing comprises dissolving a portion of the spacer wall or an adhesive bonding the spacer wall and the substrate.

13. An encapsulated micro device on a substrate, comprising:
a micro device on a substrate within a chamber;
an encapsulation cover in part defining the chamber;
a spacer wall between the substrate and the encapsulation cover, wherein the spacer wall has an inner surface adjacent to the micro device and an outer surface opposite to the inner surface, wherein the outer surface is sloped relative to the substrate; and
a sealing material on the outer surface of the spacer wall, hermetically sealing the chamber.

14. The encapsulated micro device of claim 13, wherein the spacer wall comprises a low out-gassing and low permeability material.

15. The encapsulated micro device of claim 14, wherein the spacer wall comprises epoxy or glass.

16. The encapsulated micro device of claim 13, wherein the encapsulation cover is transparent to visible, UV, or IR light.

17. The encapsulated micro device of claim 13, further comprising an opaque aperture layer on the encapsulation cover, wherein the opaque aperture layer comprises an opening over a portion of the encapsulation cover above the micro device.

18. The encapsulated micro device of claim 13, wherein the micro device comprises a tiltable mirror.

19. The encapsulated micro device of claim 13, further comprising an electric contact on the substrate, where the electric contact is configured to send an electric signal to or receive an electric signal from the micro device.

20. The encapsulated micro device of claim 19, wherein the electric contacts and the micro devices are positioned on a single surface of the substrate.

21. The encapsulated micro device of claim 19, wherein the electric contacts are positioned on a surface of the substrate that is opposite to a surface of the substrate on which the micro devices are positioned.
